(19) United States
(12) Patent Application Publication
(10) Pub. No.: US 2024/0206300 A1
(43) Pub. Date: Jun. 20, 2024

(54) DISPLAY DEVICE

(71) Applicant: LG Display Co., Ltd., Seoul (KR)

(72) Inventors: Sanghyun LEE, Paju-si (KR); Youngki SONG, Paju-si (KR); Minsoo PARK, Paju-si (KR)

(21) Appl. No.: 18/514,692

(22) Filed: Nov. 20, 2023

(30) Foreign Application Priority Data
Dec. 20, 2022 (KR) 10-2022-0179496

(51) Int. Cl. H10K 59/80

(52) U.S. Cl. CPC H10K 59/8792; H10K 59/879

(57) ABSTRACT

The display device according to an embodiment includes a display panel including a display area in which a plurality of pixels are arranged and a transparent area around the display area and an optical control film arranged below the display panel, wherein the optical control film includes a first substrate, a second substrate facing the first substrate, a first member arranged within the display area on the first substrate, and a second member arranged around the first member on the first substrate, the first member being greater in height than the second member. A light path control member includes a first substrate, a first electrode arranged on the first substrate, an option conversion unit arranged on the first electrode, a second substrate arranged on the optical conversion unit, a second electrode arranged between the second substrate and the optical conversion unit, and a barrier arranged on the top surface of the second substrate.

### CROSS REFERENCE TO RELATED APPLICATION

The present application claims priority to Korean Patent Application No. 10-2022-0179496, filed Dec. 20, 2022, the entire contents of which is incorporated herein for all purposes by this reference.

### BACKGROUND

### Technical Field

The present disclosure relates to a display device.

### Description of the Related Art

Dimming films, attached to the front of display panels in devices such as mobile phones, laptops, tablet personal computers (PCs), car navigation systems, and touchscreens in cars, block light transmitted from the light source and adjust the optical viewing angle according to the incident angle of the light to provide users with clear image quality for users at the desired viewing angle when the display transmits the screen image.

Dimming films can also be used on windows of vehicles or buildings to partially block external light to prevent glare or to make the inside of space not visible from the outside.

That is, a dimming film can be an optical path transforming material that controls the direction of light by blocking light in certain directions and allowing light to pass through in specific directions.

### BRIEF SUMMARY

The present disclosure aims to provide a transparent display device capable of switching between a first mode (transparent mode) and a second mode (dimming mode).

The objects of the present disclosure are not limited to the aforesaid, and other objects not described herein with be clearly understood by those skilled in the art from the descriptions below.

In order to accomplish the above objects, a display device according to an embodiment includes a display panel including a display area in which a plurality of pixels are arranged and a transparent area around the display area and an optical control film arranged below the display panel, wherein the optical control film includes a first substrate, a second substrate facing the first substrate, a first member arranged within the display area on the first substrate, and a second member arranged around the first member on the first substrate, the first member being greater in height than the second member. A light path control member includes a first substrate, a first electrode arranged on the first substrate, an option conversion unit arranged on the first electrode, a second substrate arranged on the optical conversion unit, a second electrode arranged between the second substrate and the optical conversion unit, and a barrier arranged on the top surface of the second substrate. Therefore, by controlling the angle of light transmission through dimming films, it is possible to control the user's viewing angle.

In order to accomplish the above objects, a display device according to another embodiment a display panel including a display area in which a plurality of pixels are arranged and a transparent area around the display area, an optical control film arranged below the display panel, wherein the optical control film includes a first substrate, a second substrate facing the first substrate, a dispersion liquid between the first and second substrates, and a plurality of light-absorbing particles dispersed in the dispersion liquid, the plurality of light-absorbing particles being arranged in the display area in a first mode and in the transparent area depending on the application of an electric field.

The detailed descriptions of other embodiments are included in the specifications and drawings.

The present disclosure is advantageous in terms of providing a transparent display device capable of switching between a first mode (transparent mode) and a second mode (dimming mode).

The advantages according to the embodiments are not limited to the aforesaid, and a variety of other advantages are included within the specification.

### BRIEF DESCRIPTION OF THE SEVERAL VIEWS OF THE DRAWINGS

FIG. 1 is an exploded perspective view of a display device according to one embodiment;

FIG. 2 is a cross-sectional view taken along line I-I′ of FIG. 1;

FIGS. 3, 4, 5, 6, 7, 8 and 9 are cross-sectional views illustrating switching between a first mode and a second mode of a display device according to an embodiment;

FIG. 10 is an enlarged cross-sectional view of area A of FIG. 3;

FIG. 11 is a cross-sectional view of a display device according to another embodiment;

FIG. 12 is a cross-sectional view of a display device according to another embodiment;

FIG. 13 is a cross-sectional view of a display device according to still another embodiment; and

FIGS. 14, 15, 16 and 17 are cross-sectional views illustrating switching between a first mode and a second mode according to alternative examples of a display device according to an embodiment.

### DETAILED DESCRIPTION

Advantages and features of the present disclosure and methods of accomplishing the same may be understood more readily by reference to the following detailed description of embodiments and the accompanying drawings. The disclosed disclosure may, however, be embodied in many different forms and should not be construed as being limited to the exemplary embodiments set forth herein; rather, these exemplary embodiments are provided so that this disclosure will be thorough and complete and will fully convey the concept of the disclosure to those skilled in the art.

When it is mentioned that one device or layer is located on another device or layer, it may be understood that one device or layer is directly located on the other device or layer or that still other device or layer is interposed between the two devices or layers. Throughout the specification, the same reference numerals refer to the same components. The shapes, sizes, ratios, dimensions (e.g., length, width, height, thickness, radius, diameter, area, etc.), angles, numbers and the like disclosed in the drawings to describe embodiments of the present disclosure are merely exemplary, and thus, the present disclosure is not limited thereto. A dimension including size and a thickness of each component illustrated in the drawing are illustrated for convenience of description, and the present disclosure is not limited to the size and the thickness of the component illustrated. In some instances, an item might be shown enlarged for ease of illustration, but it is to be noted that in many of the figures, the relative dimensions including the relative size, location, and thickness of the components are correct as illustrated in various drawings submitted herewith are part of the present disclosure.

Although the terms “first,” “second,” and the like are used for describing various components, these components are not confined by these terms. These terms are merely used for distinguishing one component from the other components. Accordingly, a first component mentioned earlier may also be a second component within the technical sprit of the present disclosure.

The various features of the embodiments of the present disclosure can combined or assembled together, either partially or entirely, in a technically diverse manner, and each embodiment can be independently implemented or in conjunction with related embodiments.

Hereinafter, exemplary embodiments of the present disclosure will be described in detail with reference to accompanying drawings.

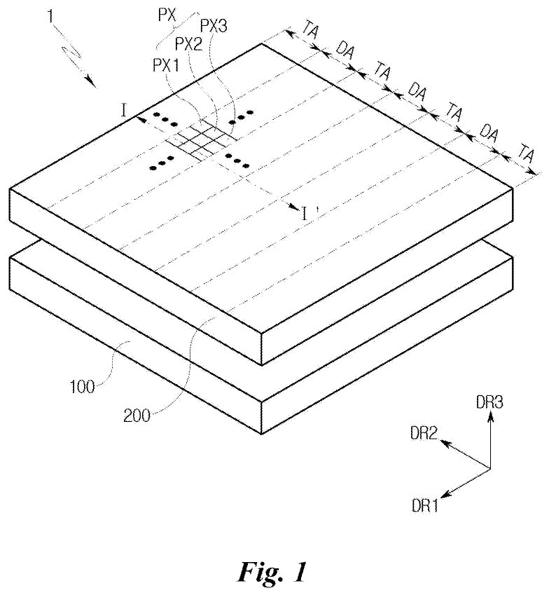

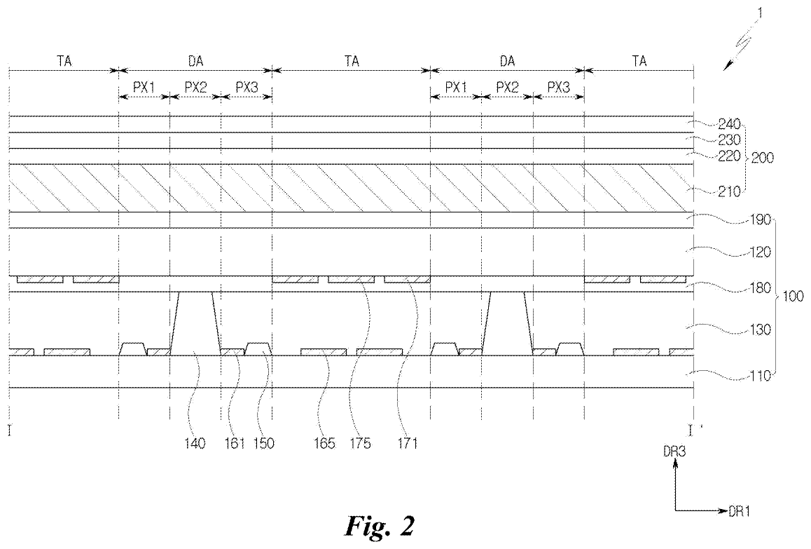

FIG. 1 is an exploded perspective view of a display device according to one embodiment. FIG. 2 is a cross-sectional view taken along line I-I′ of FIG. 1.

With reference to FIGS. 1 and 2, the display device 1 according to an embodiment may refer to any electronic device that provides a display screen. Examples of the display device 1 may include mobile phones, smartphones, tablet PCs, electronic watches, smartwatches, watch phones, mobile communication terminals, electronic notebooks, electronic books (e-books), Portable Multimedia Players (PMPs), navigation devices, game consoles, digital cameras, televisions, laptops, monitors, advertising displays, and Internet of Things (IoT) devices that are equipped with a display screen.

The display device 1 according to an embodiment may include a display panel 200 and an optical control film 100 disposed beneath, or above, the display panel 200. While the control film 100 is shown below the panel 200, namely with the panel being closer to the user, it could be positioned above it as well, namely between display panel and the user viewing the image being displayed.

The display panel 200 may be an organic light emitting diode (OLED) display panel, a liquid crystal display (LCD) panel, a plasma display panel (PDP), an electrophoretic display (EPD) panel, a microelectromechanical system (MEMS) display panel, an electrowetting display (EWD) panel, or the like. Hereinafter, the description is made under the assumption that the display panel 200 is an OLED display panel. However, the technical concept of the present disclosure is not limited to this, and various display panels may be applied to the present disclosure according to embodiments.

The display panel 200 may include a transparent area TA and a display area DA surrounding the transparent area TA. The transparent area TA and the display area DA may each be provided in multiple numbers, and the transparent area TA and the display area DA may be arranged alternately with each other. Although FIG. 1 shows that the transparent area TA and the display area DA are extended in the second direction DR2 and arranged alternately in the first direction DR1 as an example, the configuration of the transparent area TA and the display area DA is not limited thereto and may be changed in various ways.

The display area DA is an area for displaying an image and may include a plurality of pixels PX. Meanwhile, the transparent area TA may be an area that does not include a plurality of pixels PX and simply transmits the background on the back surface of the display device 1. In the first mode (or transparent mode), the transparent area TA may transmit the background on the back surface of the display device 1 as it is. On the other hand, in the second mode (or dimming mode), the background on the back surface of the display 1 may be blocked by light-absorbing particles 135 to be described later.

As shown in FIGS. 1 and 2, the display area DA of the display panel 200 may include a plurality of pixels PX, and each pixel PX may include a plurality of sub-pixels PX1, PX2, and PX3. For example, a pixel PX can include a first subpixel PX1 emitting red light, a second subpixel PX2 emitting green light, and a third subpixel PX3 emitting blue light. In addition, a pixel PX may also include a fourth subpixel that emits white light.

The display panel 200 may include a display substrate 210, a circuit component layer 220 on the display substrate 210, a light emitting component layer 230 on the circuit component layer 220, and an encapsulation layer 240 on the light emitting component layer 230.

The display substrate 210 may support the circuit component layer 220, the light emitting component layer 230, and the encapsulation layer 240 thereon. The display substrate 210 may be rigid or flexible.

In addition, the display substrate 210 may be transparent. For example, the display substrate 210 may include a transparent substrate capable of transmitting light.

The display substrate 210 may include a glass, plastic, or flexible polymer film. For example, the flexible polymer film may be made of one of polyethylene terephthalate (PET), polycarbonate (PC), acrylonitrile-butadiene-styrene copolymer (ABS), polymethyl methacrylate (PMMA), polyethylene naphthalate (PEN), polyether sulfone (PES), cyclic olefin copolymer (COC), triacetylcellulose (TAC), polyvinyl alcohol (PVA), polyimide (PI), polystyrene (PS), and this is merely an example and not necessarily limited to these materials.

In addition, the display substrate 210 may be a flexible substrate with a flexible characteristic.

In addition, the display substrate 210 can be a curved or bent substrate.

The circuit component layer 220 may include a plurality of transistors and capacitors. The circuit component layer 220 may also include gate lines, data lines, or power lines connected to the aforementioned transistors. However, it is possible that the aforementioned transistors, capacitors, gate lines, data lines, or power lines may not be arranged within the transparent area TA. The light emitting component layer 230 may include an anode electrode, an organic layer on the anode electrode, and a cathode electrode on the organic layer. However, the anode electrode and the organic layer may not be arranged in the transparent area TA. The encapsulation layer 240 may be arranged on top of the light emitting component layer 230. The encapsulation layer 240 may include at least one inorganic layer and one organic layer.

The optical control film 100 may include a first substrate 110, a second substrate 120 facing the first substrate 110, lower electrodes 161 and 165 on the first substrate 110, members 140 and 150 on the first substrate 110, a resin composite layer 130 on the lower electrodes 161 and 165 and the member 140 and 150, upper electrodes 171 and 175 on the resin composite layer 130 and the second substrate 120, a first bonding layer 180 between the upper electrodes 171 and 175 and the resin composite layer 130, and a second bonding layer 190 bonding the second substrate 120 to a display substrate 210.

The first substrate 110 may support the lower electrodes 161 and 165. The first substrate 110 may be rigid or flexible.

In addition, the first substrate 110 can be transparent. For example, the first substrate 110 may include a transparent substrate capable of transmitting light.

The first substrate 110 may include a glass, plastic, or flexible polymer film. For example, the flexible polymer film may be made of one of polyethylene terephthalate (PET), polycarbonate (PC), acrylonitrile-butadiene-styrene copolymer (ABS), polymethyl methacrylate (PMMA), polyethylene naphthalate (PEN), polyether sulfone (PES), cyclic olefin copolymer (COC), triacetylcellulose (TAC), polyvinyl alcohol (PVA), polyimide (PI), polystyrene (PS), and this is merely an example and not necessarily limited to these materials.

In addition, the first substrate 110 may be a flexible substrate with a flexible characteristic.

In addition, the first substrate 110 can be a curved or bent substrate.

The first substrate 110 may have a thickness equal to or less than 1 mm.

The second substrate 120 may support the lower electrodes 171 and 175. The second substrate 120 may be rigid or flexible.

In addition, the second substrate 120 may be transparent. For example, the second substrate 120 may include a transparent substrate capable of transmitting light.

The second substrate 120 may include a glass, plastic, or flexible polymer film. For example, the flexible polymer film may be made of one of polyethylene terephthalate (PET), polycarbonate (PC), acrylonitrile-butadiene-styrene copolymer (ABS), polymethyl methacrylate (PMMA), polyethylene naphthalate (PEN), polyether sulfone (PES), cyclic olefin copolymer (COC), triacetylcellulose (TAC), polyvinyl alcohol (PVA), polyimide (PI), polystyrene (PS), and this is merely an example and not necessarily limited to these materials.

In addition, the second substrate 120 may be a flexible substrate with a flexible characteristic.

In addition, the second substrate 120 may be a curved or bent substrate.

The second substrate 120 may have a thickness equal to or less than 1 mm.

The members 140 and 150 may be directly arranged on the top surface of the first substrate 110. The members 140 and 150 may include a first member 140 and a second member 150. The first and second members 140 and 150 may be spaced from each other in the first direction DR1. The first and second members 140 and 150 may be arranged in the display area DA. That is, the first and second members 140 and 150 may be arranged for each display area DA. A plurality of second members 150 may be arranged in one display area DA. In the display area DA, the second members 150 may be arranged to be spaced apart from the first member 140 located therebetween. Although shown as being arranged in the display area DA, the arrangement is not limited thereto, and the second member 150 may be arranged on the boundary between the display area DA and the transparent area TA.

The thickness of the first member 140 may be greater than the thickness of the second member 150. The first member 140 may be in contact, at its top surface, with the first bonding layer 180. Since the top surface of the first member 140 is in contact with the first bonding layer 180, the adjacent optical control layer 130 may be in contact only with the side surface but not the top surface of the first member 140.

Meanwhile, the top and side surfaces of the second member 150 may each be in contact with the optical control layer 130.

For example, each of the members 140 and 150 may have a trapezoidal cross-sectional shape. Each of the members 140 and 150 may have a trapezoidal cross-sectional shape with the top surface narrower than the bottom surface. However, it is obvious that the cross-sectional shape of the members 140 and 150 may be varied diversely without being limited thereto.

The lower electrodes 161 and 165 may be directly disposed on the first substrate 110. The lower electrodes 161 and 165 may include a first lower electrode 161 and a second lower electrode 165.

The first lower electrode 161 may be disposed between the adjacent first second members 140 and 150, and the second lower electrode 165 may be disposed in the transparent area TA. As described above, since the two second members 150 are arranged in one display area DA, two first lower electrodes 161 may be respectively disposed between the first member 140 and the two second members 150. The second member 150 may have a thickness greater than that of the first lower electrode 161. That is, the thickness of the first lower electrode 161 may be less than the thickness of the second member 150. Since two first lower electrodes 161 are respectively disposed between one first member 140 and two second members 150, the first lower electrodes 161 may be disposed in the display area DA. The second lower electrode 165 may be provided in plurality. That is, a plurality of second lower electrodes 165 may be arranged in the transparent area TA. Since the transparent area TA is disposed between adjacent display areas DA, a plurality of second lower electrodes 165 may be arranged between the second member 150 located on the right side of one display area DA and the second member 150 located on the left side of another display area DA in the first direction DR1.

The lower electrodes 161 and 165 may each be supplied with a certain voltage to move the light-absorbing particles 132 to be described later. The lower electrodes 161 and 165 may include conductive materials. The conductive material of the lower electrodes 161 and 165 may include photo-transparent conductive materials. The photo-transparent conductive material may include, but is not limited to, Indium-Tin Oxide (ITO), Indium-Zinc Oxide (IZO), or Indium-Gallium-Zinc Oxide (IGZO).

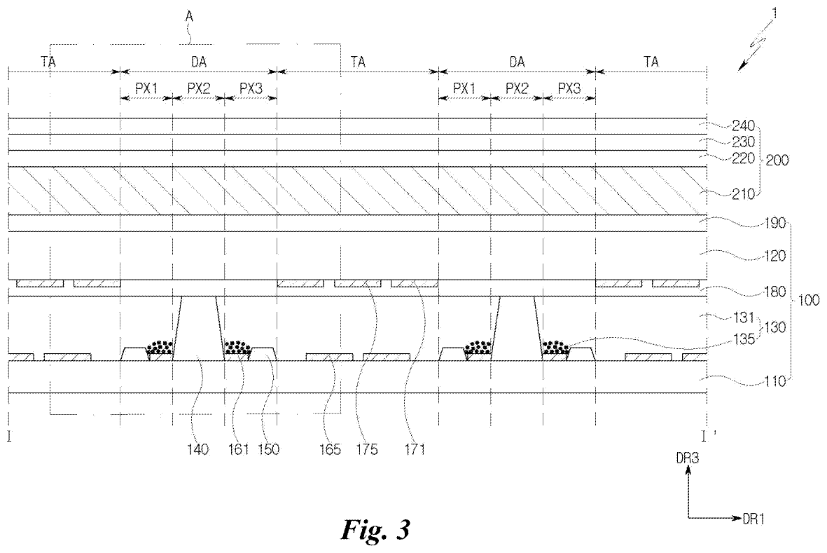

The optical control layer 130 can be disposed on the second member 150 and the lower electrodes 161 and 165. As shown in FIG. 3 to be discussed later, the optical control layer 130 may include a dispersion liquid 131 and a plurality of light-absorbing particles 135 dispersed in the dispersion liquid 131.

The dispersion liquid 131 may be a substance that disperses the light-absorbing particles 135. The term “light absorbing” with respect to particles 135 is used in the broadest sense to include light blocking or light refracting as well. Namely, the particles can be of the type that block or refract light so that it does not pass through the light control panel 100 to a location in which it can be viewed by a user. It is not required that particles 135 absorb all the light be consider light absorbing with the meaning of this specification and claims. The dispersion liquid 131 may include a transparent material. The dispersion liquid 131 may include non-polar solvents. In addition, the dispersion liquid 131 may include a substance that is capable of transmitting light. For example, the dispersion liquid 131 may include at least one of Halocarbon-based oil, paraffin-based oil, and isopropyl alcohol. In one embodiment, the dispersion material 131 may be in the form of a fluid and is not required to be a liquid. The term fluid is sufficiently broad to include liquids, but it also includes within its meaning materials that might not be considered a liquid in all modes or phases. For example, a fluid can include a slurry, a composite resin, a compressible polymer, a compressible resin, a gas, a combination of gas and many particles, a liquid and other material combinations. Thus, the term fluid, while including a liquid, is much broader since it includes any substance that can flow or have materials flow within it.

Light-absorbing particles 135 may be arranged in a dispersed manner within the dispersion liquid 131. In more detail, the plurality of light-absorbing particles 135 may be arranged in a spaced-apart manner within the dispersion liquid 131.

The light-absorbing particles 135 may include a substance capable of absorbing light. The light-absorbing particles may have colors. In more detail, the light-absorbing particles 135 may include black particles capable of absorbing light. For example, the light-absorbing particles may include carbon black particles.

The first bonding layer 180 may be disposed on the optical control layer 130. The first bonding layer 180 may serve to bond the optical control layer 130 and the second substrate 120 together. The first bonding layer 180 may include, but is not limited to, an optical transparent adhesive (OCA) or an optical transparent resin (OCR) for bonding the optical control layer 130 and the second substrate 120. The second bonding layer 190 to be described later may also include any of the materials exemplified for the first bonding layer 180.

The upper electrodes 171 and 175 may be disposed between the first bonding layer 180 and the second substrate 120. The upper electrodes 171 and 175 may be arranged in the transparent area TA. The upper electrodes 171 and 175 may include a first upper electrode 171 and a second upper electrode 175. The first upper electrode 171 may be provided in plurality. The second upper electrode 175 may be disposed between the plurality of the first upper electrodes 171. The upper electrodes 171 and 175 may be directly disposed on the bottom surface of the second substrate 120.

The upper electrodes 171 and 175 may be applied with a certain voltage to move the optical absorption particles 132 to be described later. The upper electrodes 171 and 175 may include conductive materials. The conductive material of the upper electrodes 171 and 175 may include photo-transparent conductive materials. The photo-transparent conductive material may include, but not limited to, Indium-Tin Oxide (ITO), Indium-Zinc Oxide (IZO), or Indium-Gallium-Zinc Oxide (IGZO).

Hereinafter, a description is made of switching between the first mode and the second mode of the display device 1 according to an exemplary embodiment.

FIGS. 3 to 9 are cross-sectional views illustrating switching between a first mode and a second mode of a display device according to an embodiment.

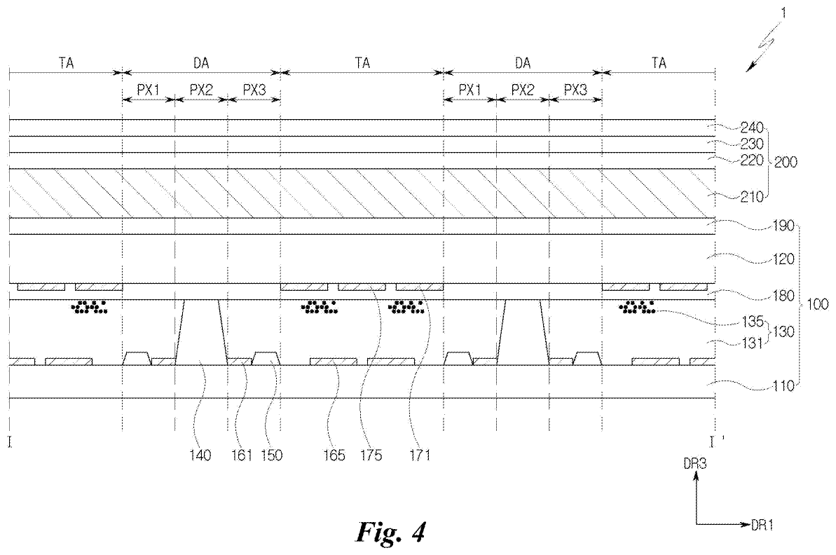

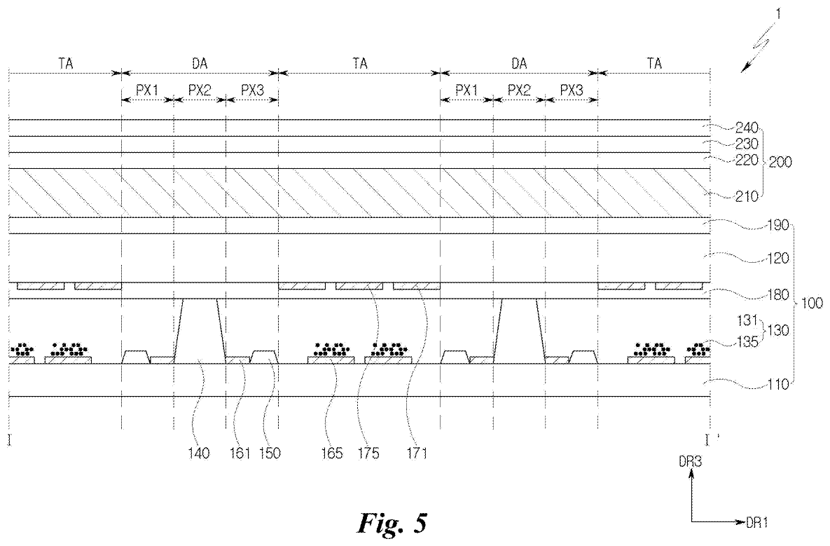

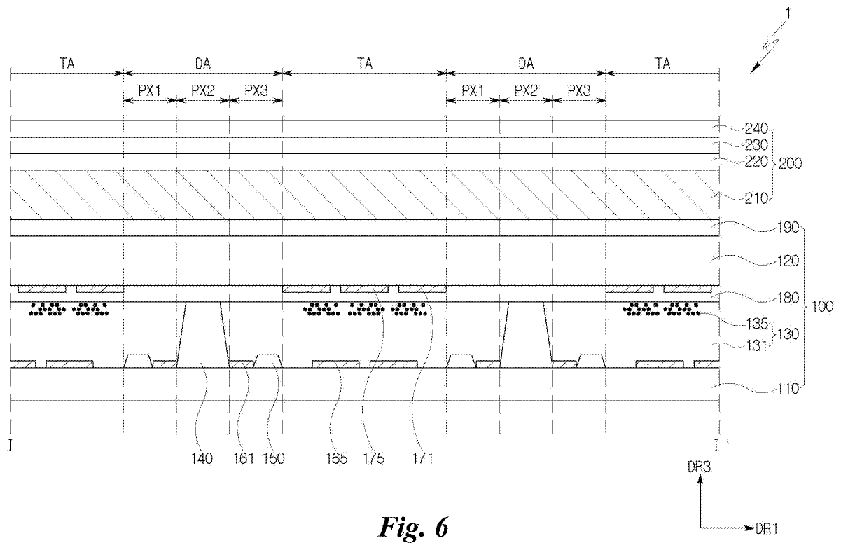

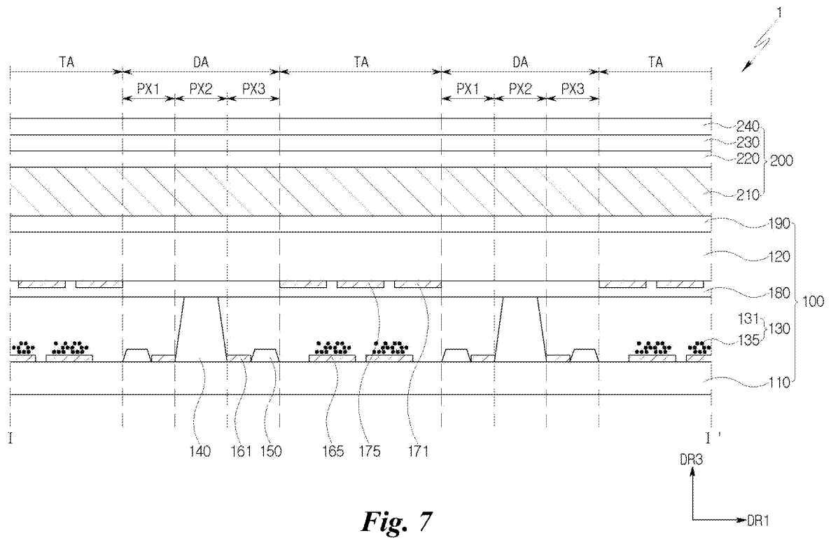

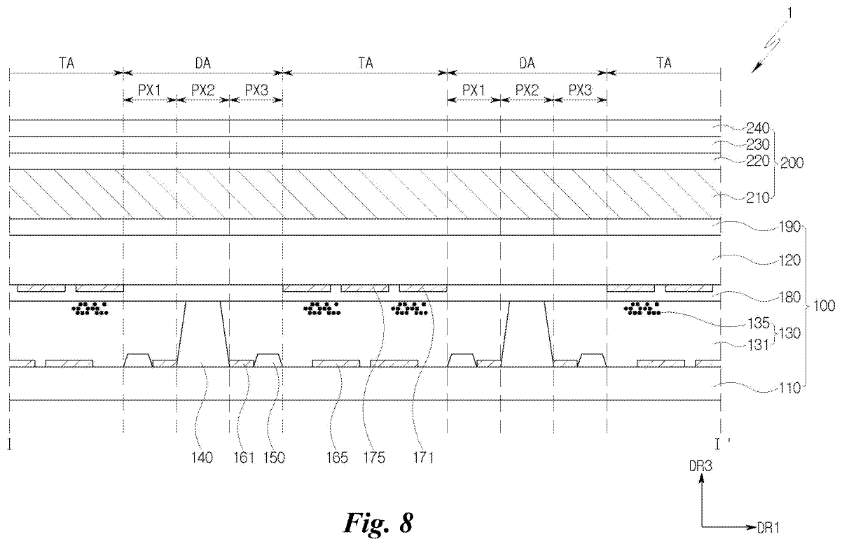

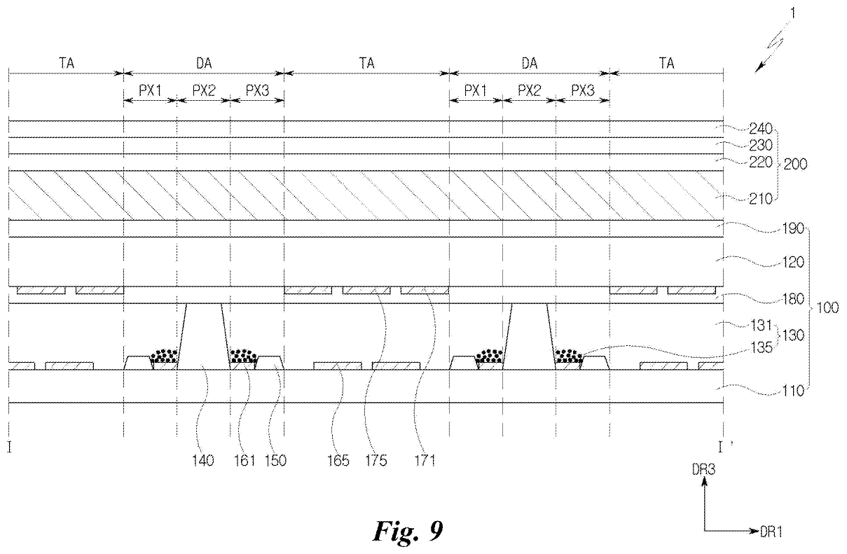

FIGS. 3 and 9 represent the first mode (or transparent mode) of the display device 1, and FIG. 6 represents the second mode (or dimming mode) of the display device 1. FIGS. 4 and 5 may represent modes that transition from the first mode to the second mode, and FIGS. 7 and 8 may represent modes that transition from the second mode to the first mode. In this embodiment, the first mode may be a mode in which the background on the back surface of the display device 1 can be transmitted to the front through the transparent area TA as the light-absorbing particles 135 are not arranged in the transparent area TA of the display device 1, and the second mode may be a mode in which the background on the back surface of the display device 1 cannot be transmitted to the front through the transparent area TA as the light-absorbing particles 135 are arranged in the transparent area TA of the display device 1 entirely.

First, as shown in FIG. 3, the light-absorbing particles 135 may be arranged throughout the display area DA. The light-absorbing particles 135 may be arranged on the first lower electrode 161 of the display area DA. The light-absorbing particles 135 may be arranged on the upper surface of the first lower electrode 161. The transition from the first mode to the second mode or from the second mode to the first mode may be achieved by the movement of the light-absorbing particles 135. That is, the light-absorbing particles 135 have charges on their surfaces, and may be moved to the lower electrodes 161 and 165 or the upper electrodes 171 and 175 depending on the characteristics of the charges and the voltage applied to them. That is, the light-absorbing particles 135 may be electrophoretic particles.

In this specification, expressing that the light-absorbing particles 135 are arranged adjacent to a member may mean that more than 80% of the light-absorbing particles 135, based on the thickness of the member, may be accumulated to a distance twice the thickness of the member from the top surface of the member and, simultaneously more than 80% of the light-absorbing particles 135, based on the width of the member, may be positioned between a first reference line corresponding to 20% of the width of the member from one side of the member (e.g., the other side in the first direction DR1) to the other side in the first direction DR1 and a second reference line corresponding to 20% of the width of the member from the other side of the member (e.g., one side in the first direction DR1) to one side. The member may be the first lower electrode 161 or the second lower electrode 165.

Meanwhile, since the first bonding layer 180 is disposed on the bottom surface of the first upper electrode 171 and the second upper electrode 175, expressing that the light-absorbing particles 135 are arranged adjacent to the first upper electrode 171 or the second upper electrode 175 may mean that more than 80% of the light-absorbing particles 135, based on the thickness of the first upper electrode 171 or the second upper electrode 175, may be accumulated to a distance twice the thickness of the first bonding layer 180 from the bottom surface of the first bonding layer 180, and simultaneously, more than 80% of the light-absorbing particles 135, based on the width of the first upper electrode 171 or second upper electrode 175, may be positioned between a first reference line corresponding to 20% of the width of the first upper electrode 171 or the second upper electrode 175 from one side of the first upper electrode 171 or the second upper electrode 175 (e.g., the other side in the first direction DR1) to the other side in the first direction DR1 and a second reference line corresponding to 20% of the width of the first upper electrode 171 or the second upper electrode 175 from one side of the first upper electrode 171 or the second upper electrode 175 (e.g., one side in the first direction DR1) to one side.

In the first mode, the light-absorbing particles 135 may be arranged between the adjacent first member 140 and second member 150. As described above, since the thickness of the first member 140 and the thickness of the second member 150 are both greater than the thickness of the first lower electrode 161, the light-absorbing particles 135 may be easily arranged adjacent to the first lower electrode 161 in the first mode.

In the first mode as represented in FIG. 3, voltage may not be applied to each of the electrodes 161, 165, 171, and 175. In order for the light-absorbing particles 135 to be arranged adjacent to the first lower electrode 161 in the first mode, the optical control layer 130 may include additives that form an electrical attraction with the negatively (−) charged light-absorbing particles 135.

Next, as represented in FIG. 4, a negative (−) voltage may be applied to the first lower electrode 161 while a positive (+) voltage may be applied to the first upper electrode 171. As a result, the light-absorbing particles 135 may move from the first lower electrode 161 to the first upper electrode 171 and be arranged adjacent to the surface of the first upper electrode 171. In some embodiments, in the mode of FIG. 4, a negative (−) voltage may be applied further to the second lower electrode 165, while a positive (+) voltage may be applied to the first upper electrode 171 and no voltage may be applied to the first lower electrode 161.

Next, as represented in FIG. 5, a positive (+) voltage may be applied to the second lower electrode 165 while a negative (−) voltage may be applied to the first upper electrode 171. As a result, the light-absorbing particles 135 may move from the first upper electrode 171 to the second lower electrode 165 and be arranged adjacent to the surface of the second lower electrode 165. In some embodiments, a positive (+) voltage may be applied only to the second lower electrode 165 while no voltage may be applied to the first upper electrode 171.

Next, as represented in FIG. 6, a positive (+) voltage may be applied to each of the upper electrodes 171 and 175 while a negative (−) voltage may be applied to the second lower electrode 165. As a result, the light-absorbing particles 135 may be arranged adjacent to each of the upper electrodes 171 and 175. In some embodiments, a positive (+) voltage may be applied only to each of the upper electrodes 171 and 175 while no voltage may be applied to the second lower electrode 165. The second mode represented in FIG. 6 may be a dimming mode. In the dimming mode, the light-absorbing particles 135 may be arranged adjacent to the upper electrodes 171 and 175, so that the background of the display device 1 on the back surface in the transparent area TA may not be visible to the user from the front.

FIG. 7 to FIG. 9 show the transition from the second mode of FIG. 6 back to the first mode of FIG. 3.

As represented in FIG. 7, a negative (−) voltage may be applied to each of the upper electrodes 171 and 175 while a positive (+) voltage may be applied to the second lower electrode 165. As a result, the light absorbing particles 135 may move from the upper electrodes 171 and 175 to the second lower electrode 165 and may be arranged adjacent to the surface of the second lower electrode 165. In some embodiments, a positive (+) voltage may be applied only to the second lower electrode 165 while no voltage may be applied to the upper electrodes 171 and 175.

As represented in FIG. 8, a positive (+) voltage may be applied to the first upper electrode 161 while a negative (−) voltage may be applied to the second lower electrode 165. As a result, the light-absorbing particles 135 may move from the second lower electrode 165 to the first upper electrode 161 and may be arranged adjacent to the surface of the first upper electrode 161. In some embodiments, a positive (+) voltage may be applied only to the first upper electrode 161 while no voltage is applied to the second lower electrode 165.

As represented in FIG. 9, a negative (−) voltage may be applied to the first upper electrode 171 while a positive (+) voltage may be applied to the first lower electrode 161. As a result, the light-absorbing particles 135 may move from the first upper electrode 171 to the first lower electrode 161 and may be arranged adjacent to the surface of the first lower electrode 161. In some embodiments, a positive (+) voltage may be applied only to the first lower electrode 161 while no voltage is applied to the first upper electrode 171.

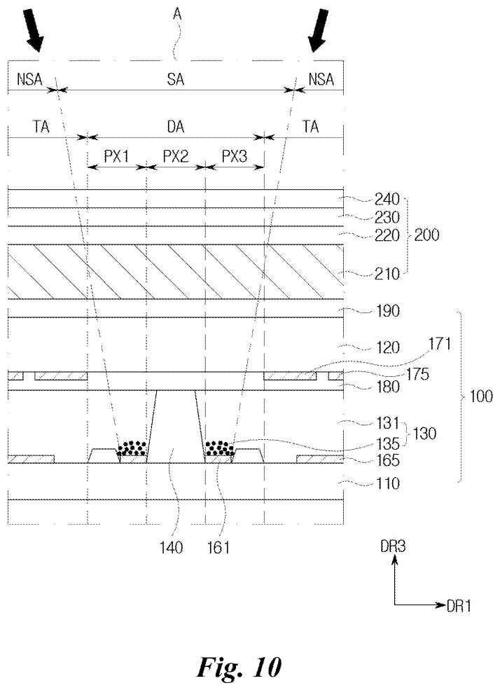

FIG. 10 is an enlarged cross-sectional view of area A of FIG. 3.

With reference to FIG. 10, in the first mode (or the transparent mode), the display device (1 of FIG. 1) may include a shielding area SA that blocks the user's view on the front and a non-shielding area NSA. The shielding area SA and non-shielding area NSA in FIG. 10 may differ from the display area DA and transparent area TA described above. That is, although the shielding area SA and the non-block area NSA are the same as the display area DA and the transparent area TA, respectively, when the user views the display device 1 in the direction of front to back (or vertically) in the first mode; the non-block area NSA may include a portion of the display area DA, and the remaining area of the non-block area NSA may be the shielding area SA when the user views the display device 1 from the side direction in the first mode.

Meanwhile, in this embodiment, the light-absorbing particles 135, in the first mode, are arranged in the space between adjacent members 140 and 150 that are greater in thickness than the first lower electrode 161, which means that the light-absorbing particles 135 are only arranged in the space between the second member 150 around the first members 140. As a result, when the user views the display device 1 from the side direction in the first mode, the area of the non-shielding area NSA becomes larger than the transparent area TA, resulting in improvement of the quality of the display device 1 in the first mode.

Furthermore, in the case where the user views the display device 1 from the side direction in the first mode, when a refractive index difference occurs between the second member 150 and the optical control layer 130, optical distortion caused by the refractive index difference may occur at the interface between the second member 150 and the optical control layer 130. Accordingly, it is preferable that the difference in refractive index between the second member 150 and the optical control layer 130 is within about 0.2. Meanwhile, because the first member 140 is not visible to the user when viewing the display device 1 from the side direction in the first mode, the refractive index of the first member 140 may differ from that of the second member 150, and the difference in refractive index between the first member 140 and the optical control layer 130 may be greater than about 0.2 or may be equal to or less than about 0.2. In one embodiment, the control layer 130 has a first refractive index, the first member 140 has a second refractive index and the second member 150 has a third refractive index. In this embodiment, each of the structures 130, 140 and 150 are transparent, but they each have a different refractive index.

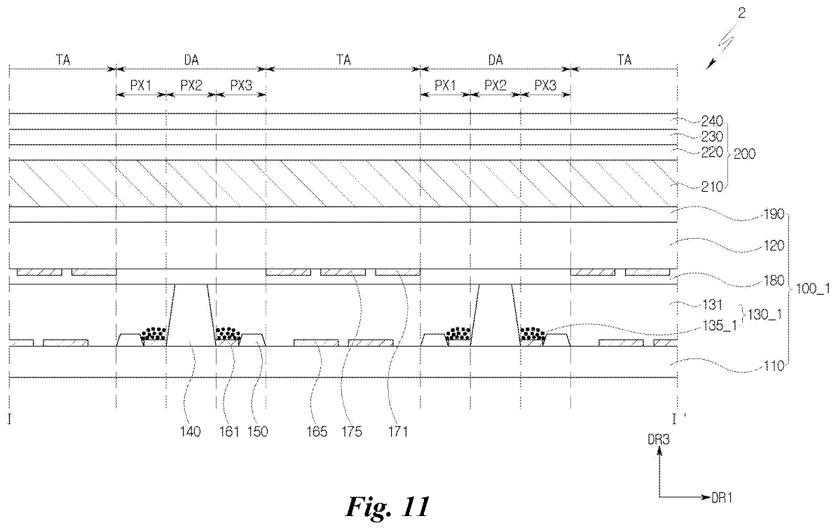

FIG. 11 is a cross-sectional view of a display device according to another embodiment.

With reference to FIG. 11, the optical control layer 130_1 of the display device 2 according to this embodiment is different from that of the display device 1 in FIG. 3 in that it does not include the aforementioned additives.

In more detail, because the optical control layer 130_1 does not include the additives, a positive (+) voltage may be applied to the first bottom electrode 161 to arrange the light-absorbing particles 135_1 adjacent to the first lower electrode 161, as shown in FIG. 11.

The additional description that has already been made with reference to FIG. 3 will be omitted.

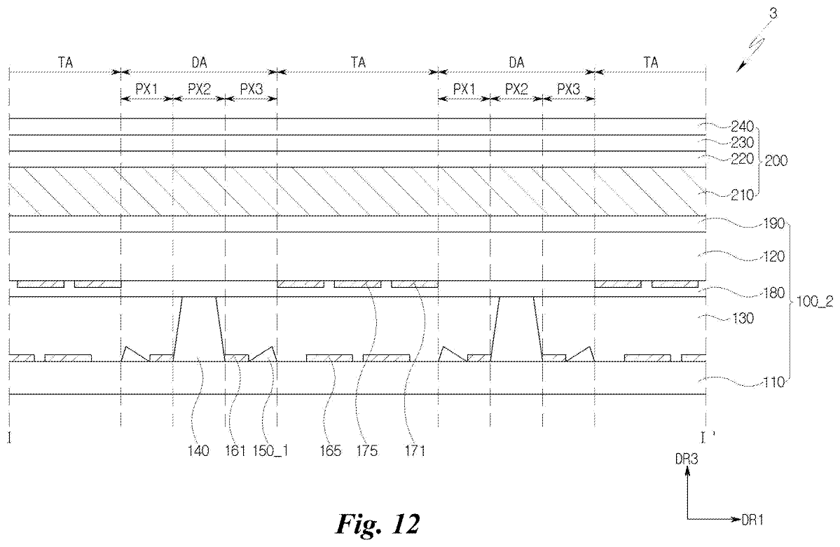

FIG. 12 is a cross-sectional view of a display device according to another embodiment.

With reference to FIG. 12, the cross-sectional shape of the second member 150_1 of the display device 3 according to this embodiment is different from that of the second member 150 in FIG. 3 in that it has a triangular shape.

The second member 150_1 may include a bottom surface in contact with the first substrate 110, a first side surface adjacent to the first member 140, and a second side surface adjacent to the transparent area TA. The bottom surface, the first side surface, and the second side surface may form a triangular shape. The length of the first side surface may be longer than that of the second side surface, but is not necessarily limited thereto.

The additional description that has already been made with reference to FIG. 2 will be omitted.

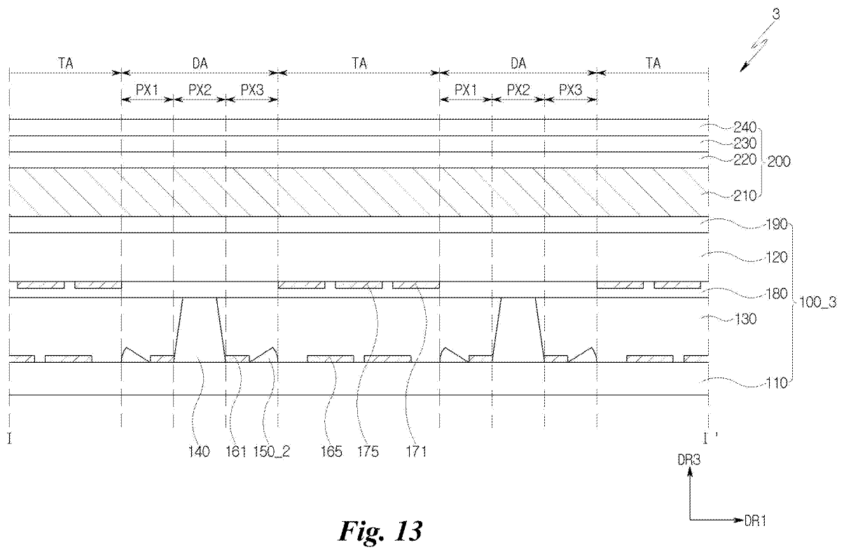

FIG. 13 is a cross-sectional view of a display device according to still another embodiment.

With reference to FIG. 13, the cross-sectional shape of the second member 150_2 of the display device 4 according to this embodiment is different from that of the second member 150_1 in FIG. 12 in that the second side surface is curved. For example, the second member 150_2 may have an arc-shaped profile.

The additional description that has already been made with reference to FIG. 12 will be omitted.

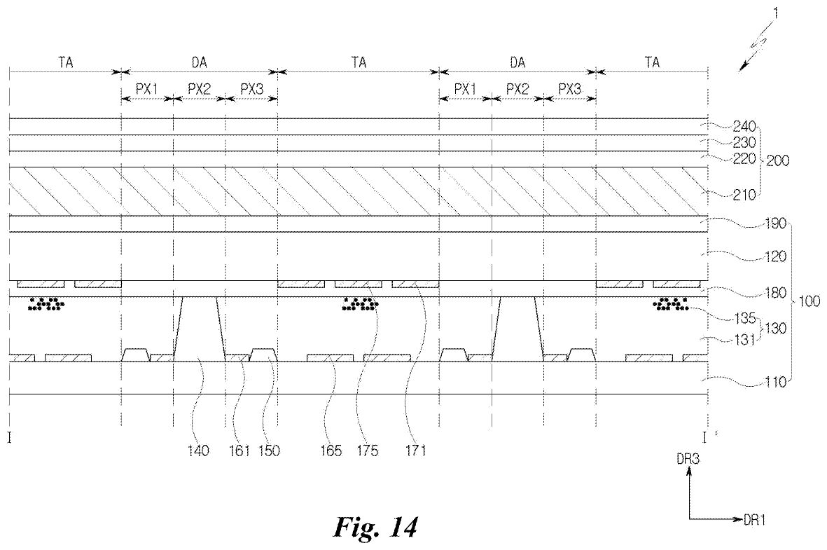

FIGS. 14 to 17 are cross-sectional views illustrating switching between a first mode and a second mode according to alternative examples of a display device according to an embodiment.

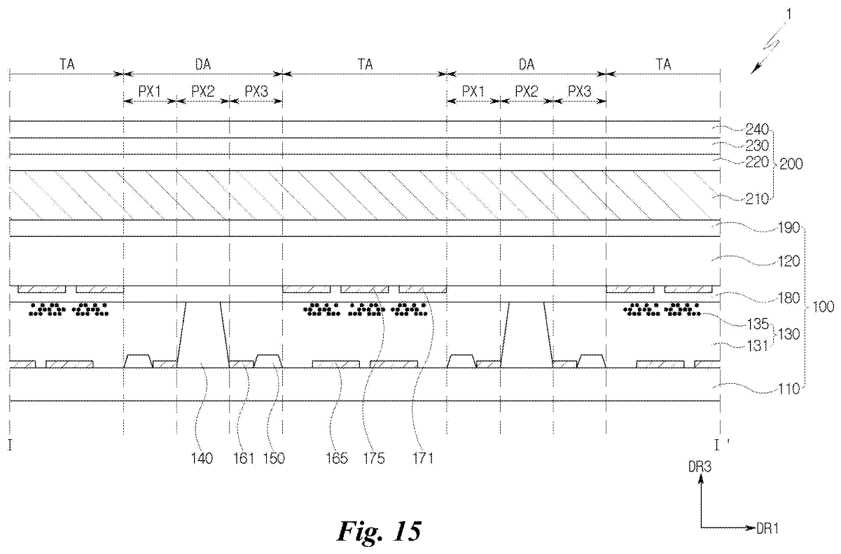

With reference to FIGS. 14 and 15, the transition from the first mode to the second mode in this embodiment may be simpler than the transition from the first mode to the second mode in FIGS. 4 to 6. That is, in the first mode of FIG. 3, a positive (+) voltage may be applied to the upper electrode 175, and a negative (−) voltage may be applied to the lower electrode 161. In some embodiments, a negative (−) voltage may be applied to the lower electrode 165 too. As a result, the light-absorbing particles 135 may be arranged adjacent to the upper electrode 175.

Sequentially, as shown in FIG. 15, a positive (+) voltage may be applied to the upper electrode 171, causing some of the light absorbing particles 135 adjacent to the upper electrode 175 to move from the upper electrode 175 to the upper electrode 171, allowing the light absorbing particles 135 to be adjacent to both the upper electrode 171 and the upper electrode 175.

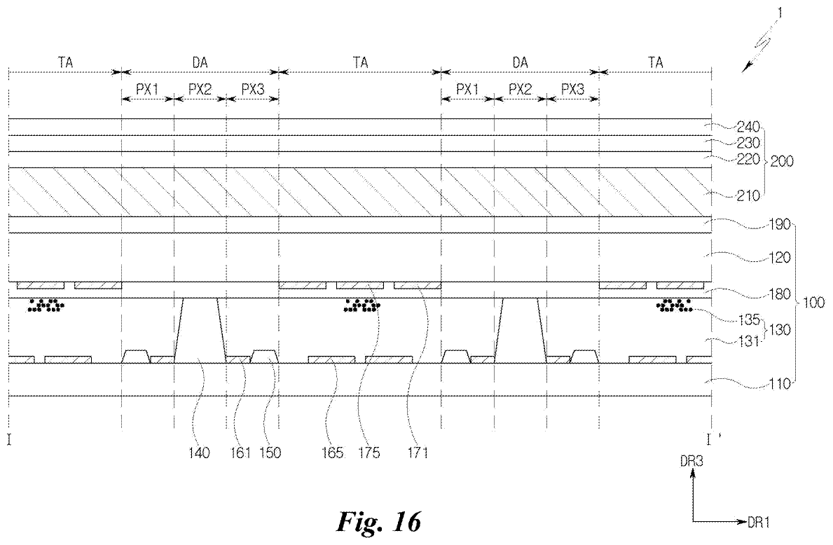

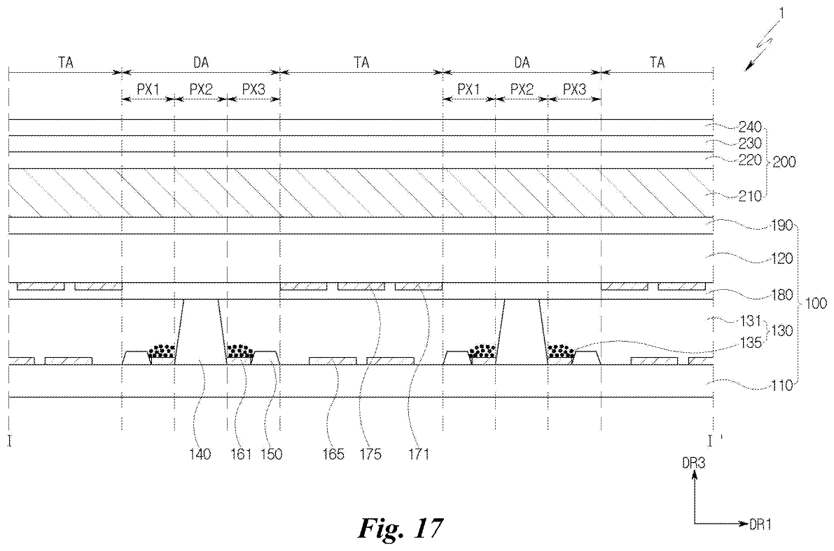

With reference to FIGS. 16 and 17, the transition from the second mode to the first mode according to this embodiment may be simpler than the transition from the second mode to the first mode in FIGS. 7 to 9.

That is, in the second mode of FIG. 15, a positive (+) voltage may be applied to the second upper electrode 175 while no voltage may be applied to the first upper electrode 171. As a result, the light-absorbing particles 135 adjacent to the first upper electrode 171 may move to the second upper electrode 175 and be arranged adjacent to the second upper electrode 175. Next, as represented in FIG. 17, a negative (−) voltage may be applied to the second upper electrode 175 and a positive (+) voltage may be applied to the first lower electrode 161. As a result, the light-absorbing particles 135 may move from the second upper electrode 175 to the first lower electrode 161 and be arranged adjacent to the first lower electrode 161.

In some embodiments, while the light-absorbing particles 135 are arranged adjacent to the second upper electrode 175 as shown in FIG. 14, some of the light-absorbing particles 135 may also be arranged adjacent to the first lower electrode 161. This is because the distance between the second upper electrode 175 and the first lower electrode 161 is greater than the distance between the first lower electrode 161 and the first upper electrode 171.

Although embodiments of this disclosure have been described above with reference to the accompanying drawings, it will be understood by those skilled in the art that this disclosure can be implemented without departing the technical concept of this disclosure. Therefore, it should be understood that the embodiments described above are exemplary and not limited in all respects.

Patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device comprising:
a display panel having a display area in which a plurality of pixels are positioned and a transparent area adjacent to the display area; and
an optical control film arranged below the display panel,
wherein the optical control film comprises:
a first substrate;
a second substrate facing the first substrate;
a first member positioned to overlap the display area on the first substrate; and
a second member positioned adjacent to the first member on the first substrate,
wherein the first member is greater in height than the second member.

2. The display device of claim 1, wherein the first member is in contact, on the top surface thereof, with the second substrate.

3. The display device of claim 1, further including: a plurality of second members that are spaced apart from each other with the first member therebetween two respective second members.

4. The display device of claim 1, wherein the second member is positioned with a first side located at a boundary between the display area and the transparent area.

5. The display device of claim 1, further comprising a first lower electrode positioned in the display area on the first substrate, the first lower electrode being arranged between the first and second members.

6. The display device of claim 5, further comprising a second lower electrode positioned in the transparent area on the first substrate.

7. The display device of claim 6, further including a plurality of second lower electrodes.

8. The display device of claim 6, further comprising a first upper electrode positioned in the transparent area on a bottom surface of the second substrate.

9. The display device of claim 8, further comprising a second upper electrode around the first upper electrode in the transparent area on the bottom surface of the second substrate.

10. The display device of claim 9, wherein the first upper electrode is provided in plurality, and the second upper electrode is positioned between the plurality of first upper electrodes.

11. The display device of claim 9, further comprising a bonding layer covering the first and second upper electrodes.

12. The display device of claim 11, further comprising a dispersion liquid positioned between the bonding layer and the first substrate and a plurality of light-absorbing particles dispersed in the dispersion liquid.

13. The display device of claim 12, wherein the light-absorbing particles are positioned on the first lower electrode between the first and second members based on the first and second upper electrodes and the first and second lower electrodes being powered off.

14. The display device of claim 13, wherein the light-absorbing particles are positioned on a bottom surface of the first upper electrode based on a positive (+) voltage being applied to the first upper electrode.

15. The display device of claim 14, wherein the light-absorbing particles are positioned on a top surface of the second lower electrode based on the positive (+) voltage being applied to the second lower electrode.

16. The display device of claim 15, wherein the light-absorbing particles are positioned on the bottom surface of the first upper electrode and a bottom surface of the second upper electrode based on the positive (+) voltage being applied to the first and second upper electrodes.

17. The display device of claim 12, wherein the light-absorbing particles are positioned on a first lower electrode based on a positive (+) voltage being applied to the first lower electrode.

18. A display device comprising:
a display panel comprising a display area in which a plurality of pixels are positioned and a transparent area around the display area;
an optical control film positioned below the display panel,
wherein the optical control film comprises:
a first substrate;
a second substrate facing the first substrate;
an optical control layer between the first and second substrates; and
a plurality of light-absorbing particles dispersed in the optical control layer,
wherein the plurality of light-absorbing particles are positioned in the display area in a first mode and in the transparent area depending on the application of an electric field.

19. The display device of claim 18, further comprising a first member arranged in the display area on the first substrate and a second member arranged around the first member on the first substrate,
wherein the first member is greater in height than the second member.

20. The display device of claim 19, wherein the first member is in, on a top surface thereof, contact with the second substrate.

21. A display device comprising:
a display panel having a plurality of display areas and a plurality of transparent areas in between respective display areas;
a plurality of light emitting pixels positioned within each respective display area;
an optical control film positioned adjacent to the display panel,
wherein the optical control film comprises:
a first substrate;
a second substrate facing the first substrate;
an optical control fluid layer positioned between the first and second substrates;
a plurality of electrically responsive light-absorbing particles positioned in the optical control fluid layer;
a first electrode adjacent to the first substrate;
a second electrode adjacent to the second substrate;
wherein the plurality of light-absorbing particles are configured to be positioned in the display area in a first mode and in the transparent area in a second mode depending on the application of an electric field applied between the first and second electrodes.

22. The display device of claim 21 further including:
a first member adjacent to the first substrate and positioned to overlap the display area on the first substrate; and
a second member arranged adjacent to the first member on the first substrate,
wherein the first member has different light refraction from the second member, is greater in height than the second member.

23. The display device of claim 21 wherein the optical control fluid layer has a first refractive index.

24. The display member of claim 23 further including:
a first member having a second refractive index; and
a second member having a third refractive index,
wherein each of the optical control fluid layer, first member and second member are transparent and have a different refractive index.

25. The display member of claim 21 wherein the optical control fluid layer is a liquid.

26. The display member of claim 21 wherein the optical control fluid layer is a resin.
